(19) United States
(12) Patent Application Publication
(10) Pub. No.: US 2009/0266415 A1
(43) Pub. Date: Oct. 29, 2009

(54) NANOSTRUCTURES AND MATERIALS FOR PHOTOVOLTAIC DEVICES

(75) Inventors: Ginger D. Rothrock, Durham, NC (US); Jason P. Rolland, Durham, NC (US); Joseph M. Desimone, Chapel Hill, NC (US)

Correspondence Address: MORGAN, LEWIS & BOCKIUS LLP, 1701 MARKET STREET, PHILADELPHIA, PA, 19103-2921, US

(73) Assignee: Liquidia Technologies , Inc.

(21) Appl. No.: 12/306,399

(22) PCT Filed: Jun. 27, 2006
(86) PCT No.: PCT/US2007/015115

§ 371 Date: Jun. 25, 2009

Related U.S. Application Data
(60) Provisional application No. 60/817,231, filed on Jun. 27, 2006.

(51) Int. Cl. H01L 31/00

(52) U.S. Cl. 136/256; 136/259

(57) ABSTRACT

A photovoltaic device includes an encapsulation layer fabricated from an elastomeric material, such as for example a perfluoropolyether having favorable optical properties, gas permeable, scratch resistant, conformal liquid material. The encapsulation layer can also include a structured surface for manipulating and trapping light incident on the photovoltaic device.

### CROSS-REFERENCE TO RELATED APPLICATION(S)

This application is based on and claims priority to U.S. Provisional Patent Application Ser. No. 60/817,231, filed Jun. 27, 2006, which is incorporated herein by reference in its entirety.

### TECHNICAL FIELD OF THE INVENTION

Generally, the present invention is related to photovoltaic devices and methods for making photovoltaic devices. More particularly, the photovoltaic devices include encapsulation materials and light management layers fabricated with nanostructured surfaces for controlling light.

### BACKGROUND OF THE INVENTION

Solar cells or photovoltaic devices (PV) are the only true portable and renewable source of energy available today as they generate electricity by converting light energy into usable electricity. Generally, a photovoltaic device is a layered structure including four principle layers: (1) an absorber-generator, (2) a collector-conveter, (3) a transparent electrical contact, and (4) an opaque electrical contact. Two other functions are usually added to solar cells, encapsulation to improve durability and anti-reflection to increase the number of photons which penetrate into the device.

The encapsulant protects the solar cell from the environment. The encapsulant must be UV transparent, at least on one side of the solar cell such that UV energy can be transmitted therethrough. The encapsulant serves to either keep all water and gases from reaching the device, which is inevitably difficult to maintain, or be gas permeable to help facilitate removal of water and other gases. Traditionally, glass has been the most successful encapsulant thusfar, although it is limiting due to low permeability, weight, and cost.

Most of the semiconductor material systems under study for solar cells have high indices of refraction resulting in reflection from a planar surface in the range of 25 to 40 percent. In order to prevent these high reflection losses, anti-reflection layers are necessary. Currently, there are two primary approaches to the reduction of reflection losses. Texturing of the surface of the semiconductor causes multiple reflections for incoming photons, reducing the net photon loss. Single or multi-layer anti-reflection coatings reduce reflections by both index matching and interference effects. Currently, however, the current materials and techniques for encapsulating and/or reducing reflection of photovoltaic devices are inadequate and improvements are needed.

### SUMMARY OF THE INVENTION

According to some embodiments of the present invention, a photovoltaic device includes an encapsulation layer fabricated from an elastomeric material, where the elastomeric material has a surface energy of less than about 20 mN/m. In alternative embodiments, the elastomeric material has a surface energy of less than about 18 mN/m, less than about 15 mN/m, or less than about 12 mN/m. In other embodiments, the elastomeric material includes a substantially optically pure elastomeric material. In some embodiments, the elastomeric material includes a substantially gas permeable elastomeric material. In other embodiments, the elastomeric material includes a fluoroelastomer or a perfluoropolyether. In some embodiments, the elastomeric material further includes a refractive index of between about 1.4 to about 1.7 or between about 1.5 to about 1.6. In some embodiment the encapsulation layer includes a structured surface for manipulating or trapping light.

In some embodiments, the present invention includes a method for improving durability of a photovoltaic device by coating a surface of a photovoltaic device with an elastomeric material having a surface energy of less than about 20 mN/m. According to some embodiments, the elastomeric material is selected from the group of elastomeric materials including gas permeable elastomeric materials, optically pure elastomeric materials, elastomeric materials having a refractive index of between about 1.5 and about 1.6, a fluoroelastomer, and a perfluoropolyether.

In alternative embodiments of the present invention, a photovoltaic device includes a structured layer configure and dimensioned with light trapping structures on a surface of the layer, wherein the structured layer is fabricated from an elastomeric mold having a surface energy less than about 20 mN/m. In some embodiments, the structured layer is a fluoroelastomer or perfluoropolyether material.

In some embodiments of the present invention, a structured layer of a photovoltaic device includes engineered structures less than about 250 micrometers in a broadest dimension. In alternative embodiments, the engineered structures include structures less than about 200 micrometers, 100 micrometers, 90 micrometers, 80 micrometers, 70 micrometers, 60 micrometers, 50 micrometers, 40 micrometers, 30 micrometers, 20 micrometers, 10micrometers, 7 micrometers, 5 micrometers, 3 micrometers, or 1 micrometer in a broadest dimension.

In some embodiments, the structured layer includes an anti-reflective layer or light trapping layer. In some embodiments, the structure layer includes a fluoroelastomer or perfluoropolyether.

According to some embodiments, a method for fabricating a component of a photovoltaic device includes introducing a material to a mold, where the mold includes an elastomeric material having a surface energy of less than about 20 mN/m, treating the material while the material is in contact with the mold, and removing the treated material from the mold, wherein the treated material forms a structured film for trapping light applied to a photovoltaic device. In some embodiments, the elastomeric material includes a fluoroelastomer material or a perfluoropolyether material. In alternative embodiments, the material introduced to the mold includes a fluoroelastomer material or a perfluoropolyether material.

In some embodiments, the treating is selected from the group of treatments including an evaporation process, a photocuring process, a thermal curing process, a temperature process, a phase change, a solvent reduction process, and combinations thereof.

### BRIEF DESCRIPTION OF THE DRAWINGS

FIG. 1 shows a schematic for fabricating a structured layer of a photovoltaic device, according to an embodiment of the present invention;

FIG. 2 shows a schematic for fabricating isolated structures of a photovoltaic device, according to an embodiment of the present invention;

FIGS. 3A and 3B show two sharkskin patterned film layers, according to an embodiment of the present invention;

FIG. 4 shows a crosslinked PFPE film with posts 100 nm in diameter and approximately 2 micrometers tall, according to an embodiment of the present invention;

FIG. 5 shows an atomic force microscopy image of a PFPE film of dual damascene structures, according to an embodiment of the present invention;

FIG. 6 shows a scanning electron microscopy image of a photocured PFPE replica film being removed from the eye of a housefly, according to an embodiment of the present invention;

FIGS. 7 and 8 are optical images of diffraction films having line diameters of about 1 micrometer and about 5 micrometers and spacing varying from about 2 micrometers to about 40 micrometers, where FIG. 7 shows a crosslinked PFPE film and FIG. 8 shows an optical acrylate resin, according to an embodiment of the present invention; and

FIG. 9 shows a scanning electron image of a crosslinked PFPE brightness enhancing film having line structures of width about 25 micrometers and having a pitch of about 50 micrometers, according to an embodiment of the present invention.

### DETAILED DESCRIPTION

According to embodiments of the present invention, photovoltaic devices can include an elastomeric based encapsulation material to improve durability of the device. According to yet another embodiment of the present invention an anti-reflection layer can be fabricated and added to the photovoltaic device to reduce reflection from the device and, thereby, increase the number of photons which penetrate into the device.

According to some embodiments, the encapsulant material protects the solar cell from the environment. The encapsulant material is UV transparent, configured on at least one side of the solar cell such that UV energy can be transmitted therethrough, and the encapsulant material serves to either keep water and gases from reaching the device and/or is gas permeable to help facilitate removal of water and other gases from the device.

According to at least one embodiment in the present invention, a solar cell or photovoltaic device includes a solvent resistant elastomer-based material as the encapsulating coating, layer, or material. In further embodiments, the solar cell includes a fluorinated elastomer-based material as the encapsulating coating, layer, or material. In further embodiments, the fluorinated elastomer of the solar cell includes a perfluoropolyether (PFPE) based material, such as FLUOROCUR™ materials (Liquidia Technologies, Inc.). According to at least one embodiment of the present invention, the encapsulant layer includes an elastomeric fluoropolymer generated by use of a liquid precursor. In other embodiments, the encapsulant includes a solvent resistant elastomer-based material. In further embodiments, the encapsulant includes fluorinated elastomer-based materials, such as for example, PFPE. In some embodiments, the encapsulation or structured layer of the present invention is fabricated from a material having substantially optically pure optical properties of essentially 100% transmittance in the visible and near IR region.

According to yet another embodiment of the present invention an anti-reflection layer can be fabricated and added to the photovoltaic device to reduce reflection from the device and, thereby, increase the number of photons which penetrate into the device. According to some embodiments, the anti-reflective layer can include texturing a surface layer to reduce net photon loss or trap light within the device. In some embodiments, the patterned or textured surface can be combined with single or multi-layered coatings that further reduce reflections by both index matching and interference effects. In another embodiment, a textured layer can be built into the encapsulant layer of the photovoltaic device.

According to some embodiments, the materials of the present invention and patterned or textured layer can be fabricated according to methods and with materials and devices described in the following U.S. and PCT patent applications, each of which is incorporated herein by reference in its entirety: U.S. Provisional Patent Application Nos. 60/505,384; 60/531,531; 60/583,170; 60/604,970; 60/691,607; 60/714,961; 60/734,228; 60/544,905; 60/706,786; 60/734,880; 60/732,727; 60/799,317; 60/649,494; 60/649,495; 60/706,850; 60/757,411; 60/762,802; 60/798,858; 60/799,876; 60/811,136; 60/833,736; 60/836,633; PCT International Patent Application Nos. PCT/US04/31274; PCT/US04/42706; PCT/US04/043737; PCT/US05/004421; PCT/US05/01956; PCT/US06/23722; PCT/US06/030628; PCT/US06/34997; PCT/US06/043305; PCT/US06/31067; PCT/US06/03983; PCT/US06/030772; PCT/US06/043756; and PCT/US07/000402.

In further embodiments, the encapsulant can be a patterned fluorinated elastomer-based material. In some embodiments, the patterned fluorinated elastomer-based material is PFPE. In some embodiments, the encapsulant includes at least one PFPE layer. In some embodiments, the PFPE layer is bonded to a material with greater scratch resistance and other physical and/or mechanical properties.

According to some embodiments, the anti-reflective layer includes a fluoropolymer generated by use of a liquid precursor. In other embodiments, the fluoropolymer is PFPE. In other embodiments, the anti-reflective layer includes a solvent resistant elastomer-based material. In further embodiments, the anti-reflective layer includes fluorinated elastomer-based materials. In further embodiments, the anti-reflective layer is a patterned fluorinated elastomer-based material. In some embodiments, the patterned fluorinated elastomer-based material is PFPE. In some embodiments, the anti-reflective layer includes at least one PFPE layer. In some embodiments, the PFPE layer is bonded to a material with greater scratch resistance.

For barrier coatings in PV's, perfluoropolyether (PFPE)-based materials of the present invention exhibit several advantages which include: 1) processing of liquid precursors versus extrusion/solvent processing of traditional materials; 2) equivalent or superior UV transparency, especially in the 300-400 nm range; 3) ability to pattern micro and nano features into the barrier layer which allow for the formation of light trapping geometries to be imprinted directly into the film; 4) mechanical properties of PFPE materials can be varied over a wide range; 5) in applications where very flexible panels are needed, PFPE elastomers are superior to traditional materials; and 6) PFPE materials can be directly functionalized to adhere to other materials including ethylene vinyl acetate, a common encapsulating material for photovoltaics. Alternatively, the PFPE materials can be adhered directly to metal or other polymeric components in a PV device as described herein and in the U.S. and International patent applications incorporated herein by reference.

According to embodiments of the present invention, structures and arrays of structures are fabricated from optically clear materials to form highly efficient light trapping layer for solar cell devices. Structures and arrays of structures are fabricated by molding a material using predetermined engineered molds made of low-surface energy elastomeric materials. In some embodiments, the predetermined arrangement and/or engineered shape of the structures have a size between about 1 nm and about 10 micrometers. In other embodiments, the structures have a size between about 10 nm and about 5 micrometers. In still further embodiments, the structures have a size between about 100 nm and about 1 micrometer. In yet further embodiments, the structures have a size between about 250 nm and about 750 nm. In some embodiments, the structures can be arranged into arrays that can be organized symmetrically, in a staggered pattern, offset, with predetermined land area, with little or no land area between structures, or some combination thereof. In some embodiments, the arrays of structures can also have a variety of features, sizes, shapes, compositions, or the like assorted within each array. One example of such a combination of structure sizes and/or shapes within a single array can include, but is not limited to, a first set of structures between about 1 nm and about 200 nm in a dimension while a second set of structures of the same array can be sized between about 500 nm and about 1 micrometer in a dimension. According to other embodiments, the structures of the present invention can be sized between about 1 micrometer and 10 micrometers. According to an embodiment, the structures of the present invention can be sized between about 10 micrometers and 25 micrometers. According to yet other embodiments, the structures of the present invention can be sized between about 10 micrometer and 100 micrometers.

According to some embodiments, the structures of the array layer can be shaped as, but are not limited to, columns or pillars that are arrayed in a matrix. In alternative embodiments, the structure in arrays can be shaped as, but are not limited to a sphere, spheroidal, trapezoidal, cylindrical, square, rectangular, cone, pyramidal, amorphous, arrow-shaped, combinations thereof, and the like. In alternative embodiments, the structures can include structures such as lines or grids. In other embodiments, the structures can be configured as lines of constant thickness. In other embodiments, the structures can be configured as lines of varying thickness. In still other embodiments, the structures can be shaped as lines of varying sidewall angle. According to another embodiment, the structures can be configured as lines of constant thickness.

The array shapes can have, in some embodiments, a uniform orientation and regular spacing between the structures. In other embodiments, the array shapes can have alternating shapes, sizes, and orientations; amorphous shapes, sizes, and orientations; uniform land area between structures, alternating land area between structures, and substantially or no land area between structures; combinations thereof; or the like. In other embodiments, the array shapes can vary in height. One preferred embodiment includes a structured component layer having structures designed and oriented in the array to maximize surface area of the structured layer. In some embodiments the distance between structures, or the land area, is between about 1 nm and about 500 nm. In alternative embodiments, the distance between structures is between about 1 nm and about 100 nm. In other embodiments, the distance between structures is less than about 1 nm to about 100 nm. In further alternative embodiments, the distance between structures is between about 5 nm and about 50 nm. In still further embodiments, the distance between structures is between about 100 nm and about 500 nanometers. In other embodiments, the distance between structures can be less than, equal to, or greater than the size of the structures. In some embodiments, the distance between structures can be less than about 1 micrometer. In other embodiments, the distance between structures can be between about 1 micrometer and about 10 micrometers. According to some embodiments, the distance between structures can be between about 10 micrometers and about 50 micrometers. According to still further embodiments, the distance between structures can be between about 50 micrometers and about 100 micrometers. In yet other embodiments, the distance between structures can be less than about 250 micrometers. The preferred distance between structures can be generally determined by the pattern of structures selected for, the material selected for the application, and the anti-reflective nature or light trapping nature desired by the structured layer.

### Fabrication of a High Fidelity Structured Layer

The structured components of the present invention are structured by molding techniques using low-surface energy elastomeric templates fabricated from methods and materials described in more detail herein and in the U.S. and PCT patent applications incorporated herein by reference. In some embodiments, the molds are fabricated from low-surface energy polymeric materials, such as, but not limited to FLUOROCUR™ (Liquidia Technologies, Inc.) and perfluoropolyether (PFPE) materials described herein having a surface energy of less than about 20 mN/m. In other embodiments, the surface energy of the elastomeric material is less than about 18 mN/m. In other embodiments, the surface energy of the elastomeric material is less than about 15 mN/m. In other embodiments, the surface energy of the elastomeric material is less than about 12 mN/m. The molding techniques of the present invention can begin with, in some embodiments, replicate molding of a patterned master that has been prepared with a predetermined pattern by, for example, lithography and/or etching. The low-surface energy elastomeric materials are then introduced to the patterned master and cured, activated, or hardened to form a replicate mold of the patterned master. In alternative embodiments other materials can be used for the molds of the present invention, however, it is preferred that the surface energy of the cured mold materials is less than the surface energies of the materials to be introduced into cavities of the replicate mold.

The structured layer can have an overall size or footprint that mimics the size of the patterned master and include structure replicates of the master. Typical patterned masters have diameters ranging between 2 inch, 4 inch, 6 inch, 8 inch, and 12 inches (50 mm, 100 mm, 150 mm, 200 mm, and 300 mm wafers). Therefore, in some embodiments the overall size or footprint of the structured layer or component can mimic the size of the master and yield structured layers for photovoltaic cells ranging in footprint of 2 inch, 4 inch, 6 inch, 8 inch, and 12 inch diameters. However, it should be appreciated that the present invention is not limited to 2, 4, 6, and 8 inch diameter footprints. Rather the structured layer for photovoltaic cells of the present invention can be fabricated in any size and/or shape that a master template (e.g., silicon wafer, quartz sheet, glass sheet, nickel roll, other patterned surfaces) can be fabricated. In some embodiments, a master template can be fabricated on a continuous process and have lengths and widths that are only limited by practical manufacturing constraints. In some embodiments, the photovoltaic cells can be fabricated in sheets having 4 inch, 6 inch, 8 inch, 12 inch, 24 inch, 36 inch, or 48 inch widths and 4 inch, 6 inch, 8 inch, 12 inch, 24 inch, 36 inch, 48 inch, 60 inch, 72 inch, 84 inch, 96 inch, or continual lengths. Following fabrication, the sheets can be cut into sizes and/or shapes that are required for particular applications. One of ordinary skill in the art will appreciate the range of shapes and/or sizes the nano-structure can be fabricated into.

### Fabrication of a Photovoltaic Device of the Present Invention

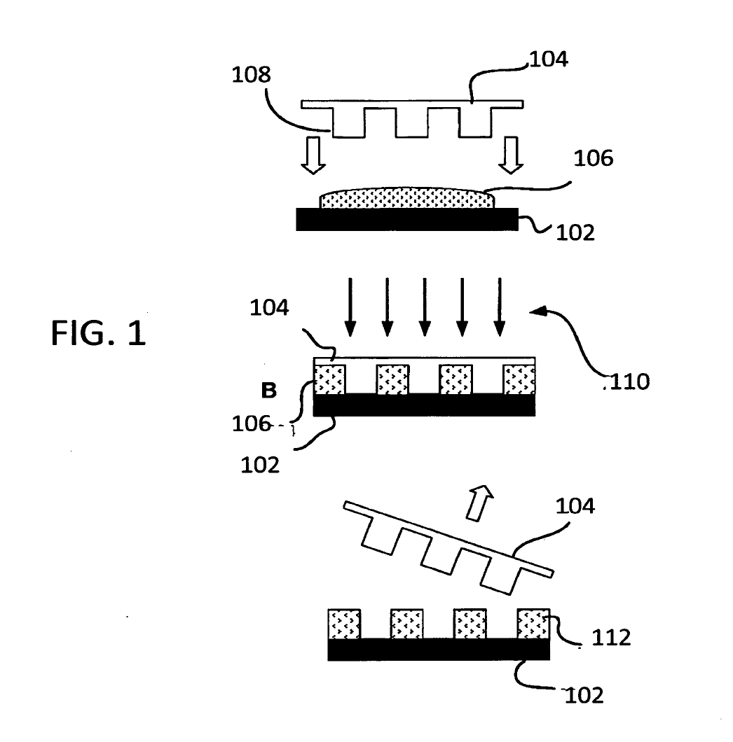

Referring now to FIG. 1, a patterned structure can be fabricated according to PRINT™ (Liquidia Technologies, Inc.) methods and as disclosed in the above referenced U.S. and PCT patent applications. According to FIG. 1, substrate 102 is provided as a backing or base for structure 112. First substance 106 is deposited onto substrate 102. According to some embodiments, first substance can be an optically pure material or anti-reflecting material. Preferably, first substance 106 is a flowable material, such as a liquid or can be manipulated into substantially a liquid state for processing: however, first substance does not have to be liquid. Next, mold 104, having a pattern 108 reflecting a pattern configured on patterned master used to make mold 104 is brought into contact with first substance 106. Patterned template is preferably brought into substantial contact with substrate 102, thereby displacing first substance 106 where pattern protrusions 108 extend from mold 104. As shown in schematic B of FIG. 1, when mold 104 is positioned with respect to substrate 102, first substance 106 is partitioned within patterned recesses 108 of mold 104. In alternative embodiments, mold 104 can be spaced a distance from substrate 102, thereby leaving first substance 106 in between patterned protrusions 108 in communication and forming a structured film.

According to another embodiment, first substance 106 is positioned directly onto mold 104 without using a substrate 102. In some embodiments, first substance 106 enters recesses of mold 104 by forces generated within the recesses, wherein such forces can include, but are not limited to atmospheric pressure, capillary forces, wetting characteristic or forces, surface tension, combinations thereof, and the like. The first substance 106 can be manually positioned on the mold, metered, or positioned on the mold by spraying or casting it onto the mold and letting a solvent evaporate to control the amounts deposited within the mold.

Next, a treatment 110 can be applied to the combination to thereby activate, polymerize, evaporate, solidify or otherwise harden first substance 106 into a solid or semi-solid. Treatment 110 can be any process, such as solvent casting, curing, and hardening processes and techniques described herein such as, but not limited to, photo-curing, thermal curing, evaporation, phase change, temperature change, combinations thereof, and the like. Once treatment process 110 is complete, mold 104 is removed from the combination of first substance 106 and substrate 102, yielding a patterned layer.

According to an embodiment, each structure 112 has a cross-sectional diameter of less than about 150 micrometers. According to alternative embodiments, each structure 112 has a cross-sectional diameter of less than about 100 micrometers, 90 micrometers, 80 micrometers, 70 micrometers, 60 micrometers, 50 micrometers, 40 micrometers, 30 micrometers, 20 micrometers, 10 micrometers, 7, micrometers, 5 micrometers, 2 micrometers, or 1 micrometer. According to yet other embodiments, each structure 112 has a cross-sectional diameter of less than about 900 nm, 800 nm, 700 nm, 600 nm, 500 nm, 400 nm, 300 nm, or 250 nm. According to other embodiments, each structure has a cross-sectional diameter of less than about 225 nm, 200 nm, 175 nm, 150 nm, 140 nm, 130 nm, 120 nm, and 110 nm. According to a more preferred embodiment, each structure 112 has a cross-sectional diameter of less than about 100 nm. According to alternate more preferred embodiments, each structure 112 has a cross-sectional diameter of less than about 95 nm, less than about 90 nm, less than about 85 nm, less than about 80 nm, less than about 75 nm, less than about 70 nm, less than about 65 nm, less than about 60 nm, less than about 55 nm, less than about 50 nm, less than about 45 nm, less than about 40 nm, less than about 35 nm, less than about 30 nm, less than about 25 nm, less than about 20 nm, less than about 15 nm, less than about 10 nm, less than about 7 nm, less than about 5 nm, or less than about 2 nm.

### Harvesting and Use of Isolated Structures

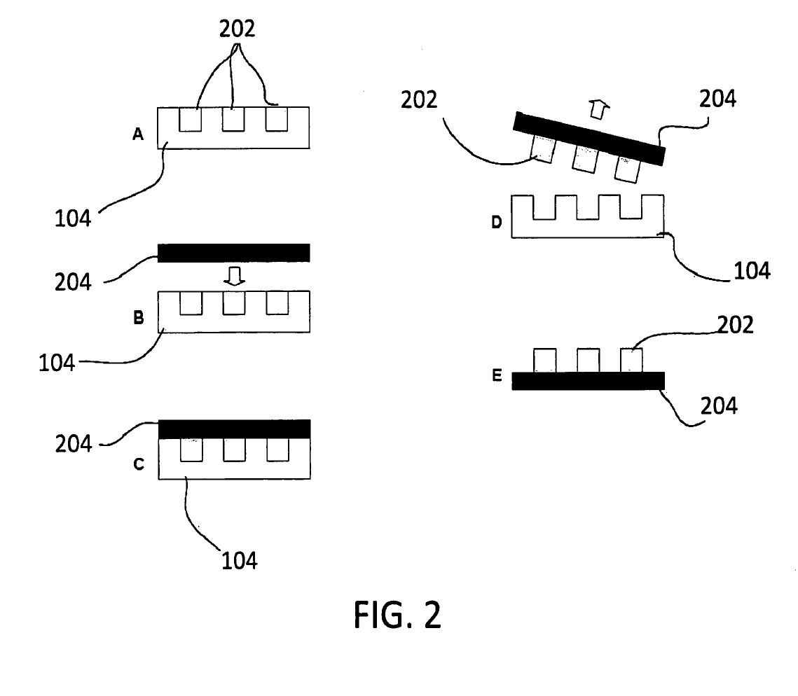

In embodiments of the present invention where structures 202 are fabricated as individual discrete particles in the recesses of mold 104, as shown in FIG. 2, the particles 202 often need to be harvested from the recesses of the mold before they can be used or applied to structured layers for photovoltaic devices. Particle 202 harvesting methods include methods described in the applicants co-pending U.S. and PCT patent applications referenced and incorporated by reference herein. According to some methods, as shown in FIG. 2, discrete particles 202 are fabricated in mold 104 as described herein. Prior to or following treatment for solidifying particles 202, film 204 having an affinity for particles 202 is put into contact with particles 202 while particles 202 remain in connection with mold 104. Film 204 generally has a higher affinity for particles 202 than the affinity between mold 104 and particles 202. In FIG. 2D, the disassociation of film 204 from mold 104 thereby releases particles 202 from mold 104 leaving particles 202 attached to film 204.

In one embodiment film 204 has an affinity for particles 202. For example, in some embodiments, film 204 includes an adhesive or sticky surface when applied to mold 104. In other embodiments, film 204 undergoes a transformation after it is brought into contact with mold 104. In some embodiments that transformation is an inherent characteristic of film 204. In other embodiments, film 204 is treated to induce the transformation. For example, in one embodiment film 204 is an polymer that hardens after it is brought into contact with mold 104. Thus when mold 104 is pealed away from the hardened polymer, particles 202 remain engaged with the polymer and not mold 104. In other embodiments, film 204 can be water that is cooled to form ice. Thus, when mold 104 is stripped from the ice, particles 202 remain in communication with the ice and not mold 104. In one embodiment, the particle-containing ice can be melted to create a liquid with a concentration of particles 202. In some embodiments, film 204 includes, without limitation, one or more of a carbohydrate, an epoxy, a wax, polyvinyl alcohol, polyvinyl pyrrolidone, polybutyl acrylate, a polycyano acrylate and polymethyl methacrylate. In alternative embodiments, particles 202 or structures can be harvested from the mold 104 by kinetic transfer, such as adhesion to a PDMS layer.

According to another embodiment, substrate 204 can be a disposable layer that is used to harvest structures 202 from mold 104. Structures 202 are maintained in an array pattern resembling the configuration of the recesses in mold 104 and then transferred to a surface of a PV device or other layer that can form a structured film component of a PV device for anti-reflective purposes or light trapping purposes as the case may be. In other embodiments, substrate 204 can include a flat film component of a PV device that is functionalized by addition of structures 202 onto a surface thereof, for the purposes of, for example, anti-reflective characteristics or light trapping.

### Micro and Nano Structures and Particles

According to some embodiments, a structure, structured layer, or particle 202 formed according to disclosed methods and techniques herein can have a shape corresponding to a mold of an engineered desired shape, geometry, and/or geometric characteristic. According to other embodiments, particles or structures 202 of many predetermined regular and predetermined irregular shape and size configurations and patterned arrays can be made with the materials and methods of the presently disclosed subject matter. Examples of representative particle and/or array structure shapes that can be made using the materials and methods of the presently disclosed subject matter include, but are not limited to, shapes and arrays disclosed in the U.S. and PCT patent application incorporated herein by reference, non-spherical, spherical, viral shaped, bacteria shaped, cell shaped, rod shaped (e.g., where the rod is less than about 200 nm in diameter), chiral shaped, right triangle shaped, flat shaped (e.g., with a thickness of about 2 nm, disc shaped with a thickness of greater than about 2 nm, or the like), boomerang shaped, trapezoid shaped, cone shaped, rectangle shaped, cube shaped, shaped into lines, hexagon shaped, combinations thereof, and the like.

### Materials from which Structures and/or Arrays of Structures are Formed

In some embodiments, the material from which the particles are formed includes, without limitation, one or more of a polymer, a liquid polymer, a solution, a monomer, a plurality of monomers, an optically pure material, a material with a refractive index of between about 1.3 and about 1.4 or between about 1.4 to about 1.7, a material with a refractive index of between about 1.5 to about 1.6, a polymerization initiator, a polymerization catalyst, an inorganic precursor, an organic material, a natural product, combinations thereof, or the like.

In some embodiments, the monomer includes butadienes, styrenes, propene, acrylates, methacrylates, vinyl ketones, vinyl esters, vinyl acetates, vinyl chlorides, vinyl fluorides, vinyl ethers, acrylonitrile, methacrylnitrile, acrylamide, methacrylamide allyl acetates, fumarates, maleates, ethylenes, propylenes, tetrafluoroethylene, ethers, isobutylene, fumaronitrile, vinyl alcohols, acrylic acids, amides, carbohydrates, esters, urethanes, siloxanes, formaldehyde, phenol, urea, melamine, isoprene, isocyanates, epoxides, bisphenol A, alcohols, chlorosilanes, dihalides, dienes, alkyl olefins, ketones, aldehydes, vinylidene chloride, anhydrides, saccharide, acetylenes, naphthalenes, pyridines, lactams, lactones, acetals, thiiranes, episulfide, derivatives thereof, and combinations thereof.

In yet other embodiments, the polymer includes polyamides, polyesters, polystyrene, polyethers, polyketones, polysulfones, polyurethanes, polysiloxanes, polysilanes, fluoropolymers, elastomers, fluoroelastomers, perfluoropolyether, cellulose, amylose, polyacetals, polyethylene, glycols, poly(acrylate)s, poly(methacrylate)s, poly(vinyl alcohol), poly(vinylidene chloride), poly(vinyl acetate), poly(ethylene glycol), polystyrene, polyisoprene, polyisobutylenes, poly(vinyl chloride), poly(propylene), poly(lactic acid), polyisocyanates, polycarbonates, alkyds, phenolics, epoxy resins, polysulfides, polyimides, liquid crystal polymers, heterocyclic polymers, conducting polymers including polyacetylene, polyquinoline, polyaniline, polypyrrole, polythiophene, and poly(p-phenylene), fluoropolymers, derivatives thereof, combinations thereof.

In some embodiments, additional components are included with the material of the nano-scale particle or structures to functionalize the particle. According to these embodiments the additional components can be encased within the isolated structures, partially encased within the isolated structures, on the exterior surface of the isolated structures, combinations thereof, or the like. Additional components can include, but are not limited to, light manipulating components, particles, and the like.

### Formation of Multilayer Structures

The present invention includes methods for forming multilayer structures, including multilayer particles, multilayer structured layers, and the like. In some embodiments, multilayer structures are formed by forming a single structured layer as described herein and thereafter fabricating isolated structures or a second structured layer onto the first structured layer. Any number of layers, orientation of structures, shapes of structures, size of structures, distribution of structures, compositions of structures or layers, combinations thereof, or the like can be fabricated as needed for particular applications or uses, as will be appreciated by one of ordinary skill in the art and all such combinations are contemplated by this present invention.

### Structures, Sizes, Shapes, and Distribution

In some embodiments, structures (112, 202) include shapes and sizes including textured particles that are about 0.5 micrometers to about 3.0 micrometers in diameter. Similar structures can be found in U.S. and PCT patent applications U.S. Pat. No. 6,420,647; WO00028603; WO00028602; U.S. Pat. No. 6,538,195, each of which are incorporated herein by reference.

In some embodiments, structures (112, 202) include shapes and sizes that can include a wavered grating, wherein the grating periodicity is of a wavelength scale such that the periodicity yields a strong diffraction regime, incident light is bent, and optical path length is enhanced. Such structures can be found in published U.S. patent application No. 2007/0000536, which is incorporated herein by reference.

In other embodiments, structures (112, 202) include shapes and sizes that form substantially elongated parallel groves disposed about 90 degrees to one another forming a square or rectangular pattern, substantially elongated parallel grooves forming generally diamond shaped texture, stipple-like line textures, grooves angled at 45 degrees to a substrate, combinations thereof, and the like. Such structures can be found in U.S. Pat. Nos. 5,306,646; and 5,503,898, which are incorporated herein by reference.

In further embodiments, structures (112, 202) include shapes and sizes that form textured surfaces having densely packed microstructures of predetermined dimensions of the order of the wavelength of visible light, identical closely packed randomly arranged microcolumnar posts, posts having height held constant in a narrow range of about 140 nm to about 220 nm with diameters varying from about 50 nm to about 2,000 nm, and an additional monolayer of colloidal particles substantially placed over the entire surface such that the particles are fixed to the substrate. Related structures are disclosed in U.S. Pat. No. 4,554,727, which is incorporated herein by reference.

In yet further embodiments, structures (112, 202) include shapes and sizes that form pyramids in the form of square base pyramids or triangular base pyramids, pyramids which are upright or tilted from vertical, inverted pyramids wherein the size of features forming the textured surface in any one dimension are generally no greater than about 10 microns or 2 times the predefined film thickness, and wherein facets are angled in a range between about 25 degrees and about 65 degrees to a horizontal reference plane and facets angled in a range between about 30 degrees and about 45 degrees to the horizontal reference plane. Similar such structures are disclosed in International patent application WO 97/19473, which is incorporated herein by reference.

In yet other embodiments, structures (112, 202) can include, pyramid structures on the order of about 14 micrometers high and about 20 micrometers on each side of a base in random locations, as disclosed in U.S. Pat. No. 4,918,030, which is incorporated herein by reference.

In further embodiments, structure (112, 202) can include a plurality of macroscopic features having a periodic spacing; width and depth on a first surface of a doped film wherein each feature has at least one surface perpendicular to the first surface of the film and one surface parallel thereto; random three dimensional microscopic structures having dimensions smaller than the wavelength or wavelengths of light; a pyramidal pattern having a period approximately equal to the period of the plurality of macroscopic features; and two dimensional hole patterns. Similar structures are disclosed in U.S. published patent application no. US2007/0084505, which is incorporated herein by reference.

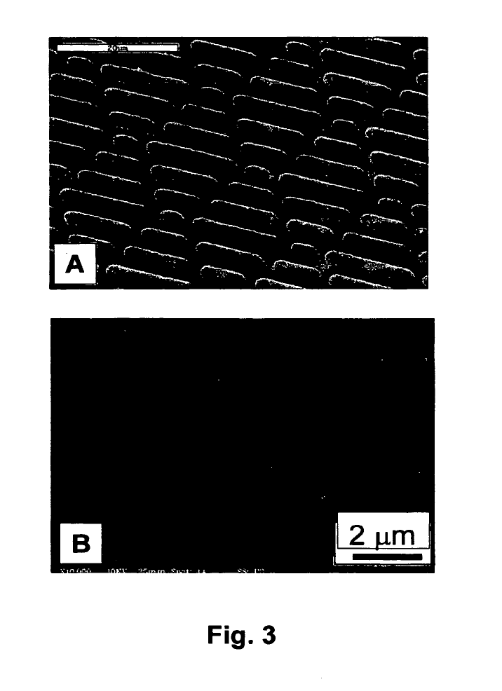

In further embodiments, the following figures represent a variety of patterned film structures created by the PRINT™ methods, materials, and devices described herein and in the references incorporated herein by reference. FIGS. 3A and 3B are two sharkskin patterns, where the feature width and depth is approximately 2 micrometers and the length is varied from between about 2 micrometers and about 15 micrometers. FIG. 3A is a patterned crosslinked PFPE film, while FIG. 3B is a triacrylate film of the reverse image at high magnification. Furthermore, the sharkskin pattern of FIGS. 3A and 3B include nm scale horizontal striations in the cavities which were replicated from the original silicon master.

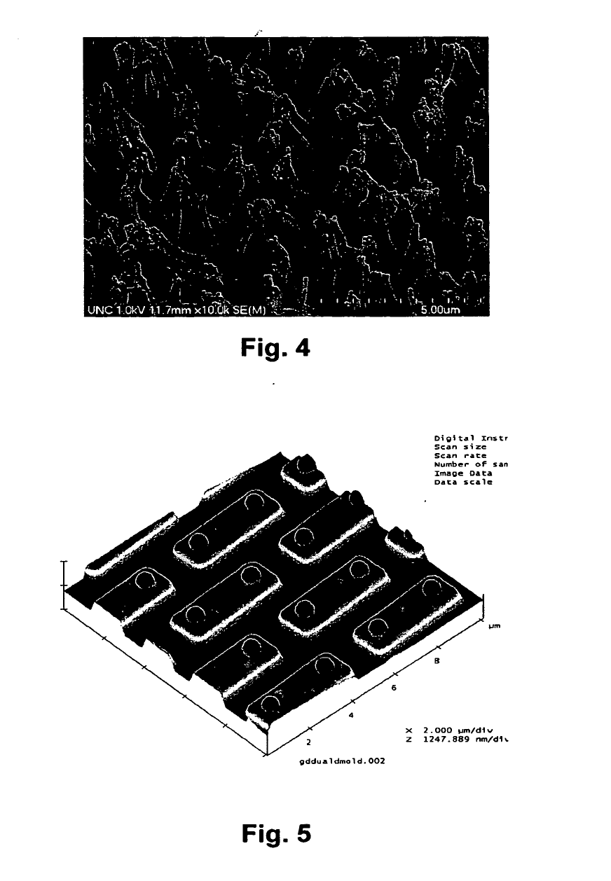

FIG. 4 shows a crosslinked PFPE film with posts 100 nm in diameter and approximately 2 micrometers tall. The PFPE film is configured with a selected low modulus such that the posts collapse on each other forming the pattern shown in FIG. 4.

FIG. 5 shows an atomic force microscopy image of a PFPE film of dual damascene structures. The large structures are approximately 2 micrometers by approximately 4 micrometers while the small protrusions on top are approximately 500 nm in diameter.

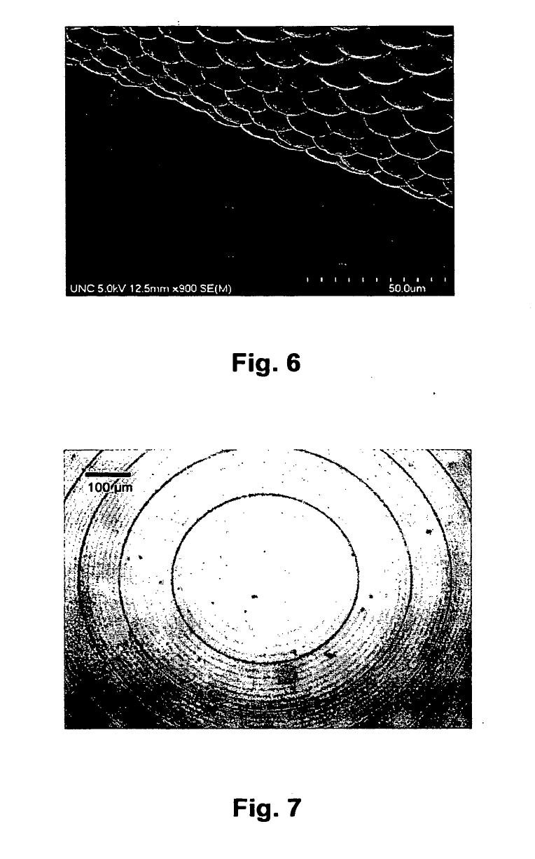

FIG. 6 shows a scanning electron microscopy image of a photocured PFPE replica film being removed from the eye of a housefly. This natural structure, the eye of a housefly, having approximately 25 micrometer lenses, was replicated with high fidelity using liquid PFPE precursor and crosslinking it with UV radiation.

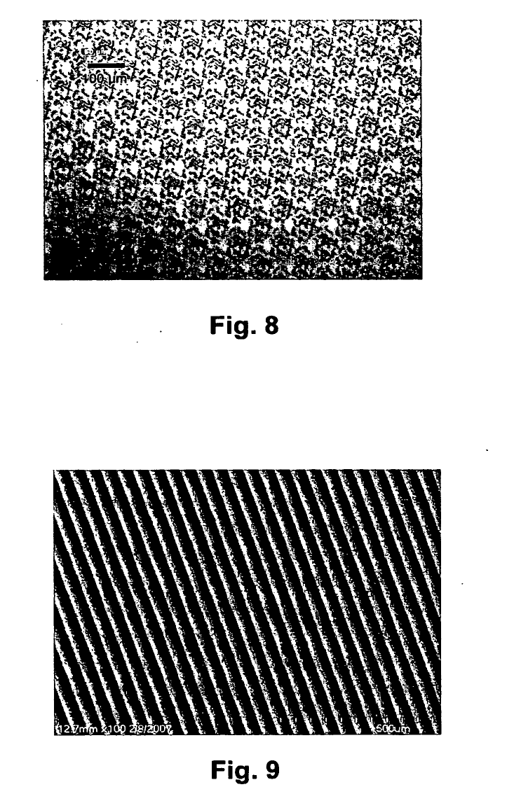

FIGS. 7 and 8 are optical images of diffraction films having line diameters of about 1 micrometer and about 5 micrometers and spacing varying from about 2 micrometers to about 40 micrometers. FIG. 7 shows a crosslinked PFPE film and FIG. 8 shows an optical acrylate resin, Norland Optical Adhesive 74, having a refractive index of 1.52.

FIG. 9 shows a scanning electron image of a crosslinked PFPE brightness enhancing film having line structures of width about 25 micrometers and having a pitch of about 50 micrometers.

### EXAMPLE

A structured film was fabricated from a patterned parylene master containing 4 patterned areas of hexagonal structures, varying from approximately 2 μm in diameter to 20 μm in diameter. A photocurable PFPE dimethacrylate was prepared (see Rolland, J. P., et al, J. Am Chem. Soc., 2004, 126, 2322-2323) and blended with 0.1 wt % 2,2-diethoxyacetophenone photoinitiator. This liquid solution is drop cast over the parylene coated wafer containing the pattern and placed in a UV-curing chamber. A slight nitrogen stream is started, and the photocurable PFPE dimethacrylate cured for 5 minutes at 365 nm radiation to form a structured film replicating the pattern of the parylene master. The structured film is removed and characterized with optical microscopy. The pattern fidelity was excellent in all cases, as measured with optical images.

The structured PFPE film was then used to pattern replicate films of a variety of UV-curable optical resins, including Masterbond UV15, Dymax 1128-M, RiteLok UV107, Epoxies, etc. 60-7100, and NOA 74. The general procedure for fabricating these patterned replicate films was as follows: the resin was drawn in a line in the middle of a clean flat 4″ wafer. The structured PFPE film was placed on the line and slowly laid down from the middle to the edges. A rubber roller was used to make an even film. The wafer was placed in a UV curing chamber and cured under 365 nm light for 5 minutes. After 3 minutes of cooling time, the structured PFPE film was lifted off to reveal a patterned optical resin film coated on the 4″ wafer. These patterned resins were evaluated for fidelity using the optical microscope (200-1000×) as well as adhesion to the mold and wafer.

All documents referenced herein are hereby incorporated by reference as if set forth in their entirety.

1. A photovoltaic device, comprising:
an encapsulation layer comprising an elastomeric material, wherein the elastomeric material has a surface energy of less than about 20 mN/m.

2. (canceled)

3. (canceled)

4. The photovoltaic device of claim 1, wherein the elastomeric material is a substantially optically pure elastomeric material.

5. (canceled)

6. The photovoltaic device of claim 1, wherein the elastomeric material comprises a substantially gas permeable elastomeric material.

7. (canceled)

8. The photovoltaic device of claim 1, wherein the elastomeric material comprises a perfluoropolyether.

9. The photovoltaic device of claim 1, wherein the elastomeric material comprises a refractive index of between about 1.3 to about 1.4.

10. The photovoltaic device of claim 1, further comprising a structure configured and dimensioned on the encapsulation layer.

11.-33. (canceled)

34. The photovoltaic device of claim 10, wherein the structure comprises a plurality of structures configured and dimensioned to trap light within the photovoltaic device.

35. The photovoltaic device of claim 34, wherein the structures of the plurality of structures are less than about 10 micrometers in a broadest dimension.

36. The photovoltaic device of claim 34, wherein the structures of the plurality of structures are less than about 1 micrometer in a broadest dimension.

37. A photovoltaic device, comprising:
an encapsulation layer comprising an elastomeric material, wherein the elastomeric material comprises a substantially optically pure material having a structured surface and wherein the structured surface includes structures configured and dimensioned to trap light within the photovoltaic device.

38. The photovoltaic device of claim 37, wherein the elastomeric material is substantially gas permeable.

39. The photovoltaic device of claim 37, wherein the elastomeric material comprises a perfluoropolyether.

40. The photovoltaic device of claim 37, wherein the elastomeric material has a refractive index of between about 1.3 to about 1.4.

41. The photovoltaic device of claim 37, wherein the structures of the structured surface are less than about 10 micrometers in a broadest dimension.

42. The photovoltaic device of claim 37, wherein the structures of the structured surface are less than about 1 micrometer in a broadest dimension.

43. A photovoltaic device, comprising:
a structured layer configured and dimensioned with a plurality of light trapping structures on a surface of the layer, wherein the structured layer is fabricated from an elastomeric material having a surface energy less than about 20 mN/m.

44. The photovoltaic device of claim 43, wherein the structured layer includes engineered structures less than about 10 micrometers in a broadest dimension.

45. The photovoltaic device of claim 43, wherein the structured layer includes engineered structures less than about 1 micrometer in a broadest dimension.

46. The photovoltaic device of claim 43, wherein the plurality of light trapping structures is configured and dimensioned into a substantially uniform array of structures having substantially identical size and shape.

47. The photovoltaic device of claim 43, wherein the elastomeric material comprises a perfluoropolyether.
